(19) United States
(12) Patent Application Publication
(10) Pub. No.: US 2015/0282293 A1
(43) Pub. Date: Oct. 1, 2015

(54) DISPLAY, DISPLAY ASSEMBLY AND DEVICE

(71) Applicant: GOOGLE TECHNOLOGY HOLDINGS LLC, Mountain View, CA (US)

(72) Inventors: David Kyungtag Lim, Green Oaks, IL (US); Steve C Emmert, McHenry, IL (US); Michael J. Formenti, Channahon, IL (US); William R. Groves, Naperville, IL (US); Ernest J. Sirois, Libertyville, IL (US); Jason P. Wojack, Libertyville, IL (US)

(21) Appl. No.: 14/616,150

(22) Filed: Feb. 6, 2015

Related U.S. Application Data
(60) Provisional application No. 61/936,963, filed on Feb. 7, 2014.

(51) Int. Cl. H05K 1/02; H05K 5/00; H05K 1/11

(52) U.S. Cl. CPC H05K 1/028; H05K 1/115; H05K 1/118; H05K 5/0017

(57) ABSTRACT

A display includes a minimal perimeter border. The display includes a front layer and a bottom layer. The bottom layer includes vias along the perimeter edge in a bonding region. A driver IC connected to the traces carried on the second surface and extending through the vias, the traces connecting to pixels generating images on the display.

### CROSS-REFERENCE TO RELATED APPLICATION

This application is a Nonprovisional of, and claims priority to, U.S. Patent Application No. 61/936,963, filed on Feb. 7, 2014, entitled “DISPLAY, DISPLAY ASSEMBLY, AND DEVICE”, which is incorporated by reference herein in its entirety.

### BACKGROUND

This background description is provided for the purpose of generally presenting the context of the disclosure. Unless otherwise indicated herein, material described in this section is neither expressly nor impliedly admitted to be prior art to the present disclosure or the appended claims.

Display assemblies typically employ a driver integrated circuit (IC) for controlling the display active area to generate images for viewing. The driver IC is sometimes carried on a flex circuit connecting the display to other electrical components of the device. Other structures carry the driver IC on a glass substrate of the display itself. The driver IC and flex circuit impact the overall design of the device, effecting the size, shape, and configuration of the device, as well as the positioning of the display in the device. An improved display assembly enabling greater flexibility in device design is needed.

### BRIEF DESCRIPTION OF THE DRAWINGS

Techniques and apparatus are described with reference to the following drawings. The same numbers are used throughout the drawings to reference like features and components.

FIG. 1 illustrates a plan view of a display assembly with a chip-on-glass (COG) driver IC and flex circuit according to the PRIOR ART.

FIG. 2 illustrates a side view of the COG driver IC and flex circuit display assembly according to FIG. 1.

FIG. 3 illustrates a plan view of a display chip-on-flex (COF) driver IC and flex circuit display assembly according to the PRIOR ART.

FIG. 4 illustrates a side view of the PRIOR ART COG driver IC and flex circuit display assembly according to FIG. 1.

FIG. 5 illustrates a plastic OLED including a COF flex and a display flex.

FIG. 6A illustrates a rear perspective view of an example rectangular display, and

FIG. 6B illustrates a front plan view of the example rectangular display of FIG. 6A.

FIG. 7 illustrates a front plan view a uniform border display device including a rectangular display assembly according to FIG. 6.

FIG. 8 illustrates a front plan view of a uniform border round display device.

FIG. 9 illustrates a front perspective view of the device according to FIG. 7.

FIG. 10 illustrates a front perspective view of the device according to FIG. 8.

FIG. 11A illustrates a plan view of a round display assembly.

FIG. 11B illustrates another plan view of a display assembly.

FIG. 11C is a table that illustrates example via counts for a 30 or 40 mm round display, such as in the round display assembly in FIG. 11A.

FIG. 12 illustrates a cross-section of the round display assembly according to FIG. 11A taken through plane 12-12.

FIG. 13 illustrates a cross-section of the round display assembly according to FIG. 11A taken through plane 13-13.

FIG. 14 illustrates an enlarged plan view of a corner of a rectangular display assembly according to the PRIOR ART.

FIG. 15 illustrates a COF display and a display including perimeter I/O pads.

FIG. 16 illustrates a display flex bond zone with routing to perimeter I/O pads.

FIG. 17 illustrates a COF flex bonded to a display flex.

FIG. 18 illustrates an enlarged plan view of a corner of a rectangular display.

FIG. 19 illustrates a plan view of the display flex with I/O pads.

FIG. 20 illustrates an anisotropic conductive adhesive (ACF) paste eutectic bond pasted onto flex I/O pads.

FIG. 21 illustrates a display flex bonded to a display rear surface.

FIG. 22 illustrates a rear surface thin film transistor (TFT) and Ecap, and an ACF eutectic I/O bond zone.

FIG. 23 illustrates application of hot bar-reflow eutectic ACF.

FIG. 24 illustrates a display assembly including a flex circuit bonded to a TFT display.

FIG. 25 illustrates an alternate embodiment of a round display assembly.

FIG. 26 illustrates a front of a display flex assembly according to FIG. 25.

FIG. 27 illustrates a rear of the display flex assembly according to FIG. 25.

FIG. 28 illustrates a cross section of a corner of a device display housing including an attached display assembly.

FIG. 29 illustrates an exploded view of a device including the display housing according to FIG. 28.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

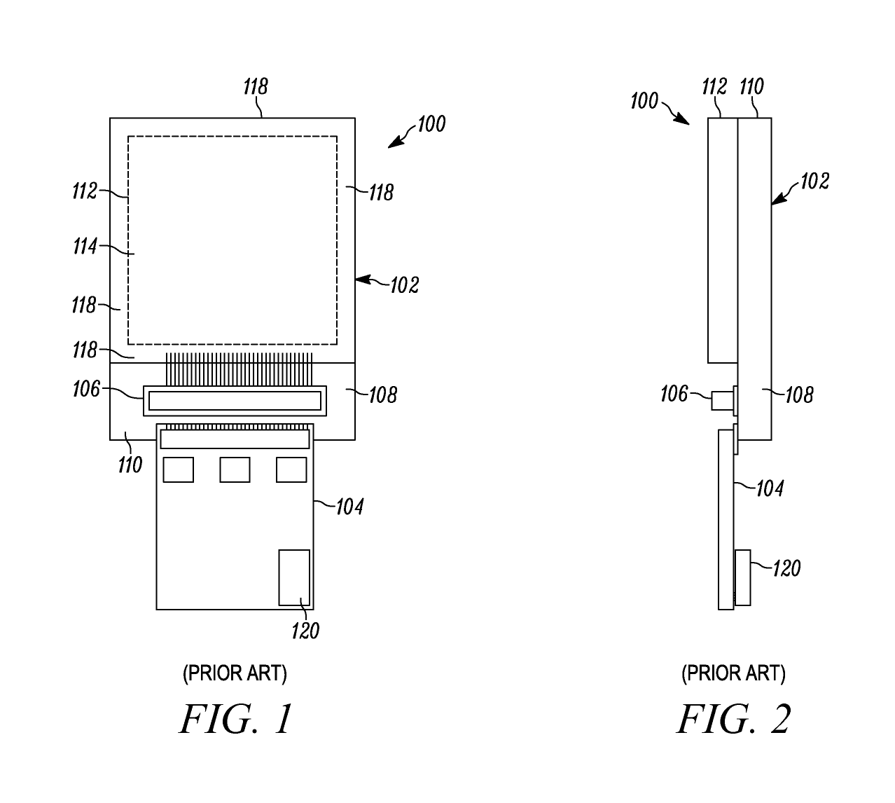

With reference to FIGS. 1 and 2, a prior art display assembly 100 includes a display 102 and a flex circuit 104. A driver IC 106 for the display 102 is mounted on a display driver ledge 108, which ledge may for example be part of a display layer 110, referred to as a thin film transistor (TFT) substrate of the display, and which ledge extends outwardly from an end, or side, of the display and beyond the upper layer of the display 112. The ledge 108 carries circuitry utilized in driving the display, and may carry a driver IC 106 bonded directly to the glass in a so called chip-on-glass (COG) construction illustrated in FIGS. 1 and 2. The display 102 includes active pixels in the active area 114 of the display, but does not include active pixels in the area of the ledge 108. The “active area” 114 of the display is the portion of the display in which images are presented using display pixels. The active area of the display is within a perimeter border 118 of the display upper layer 112.

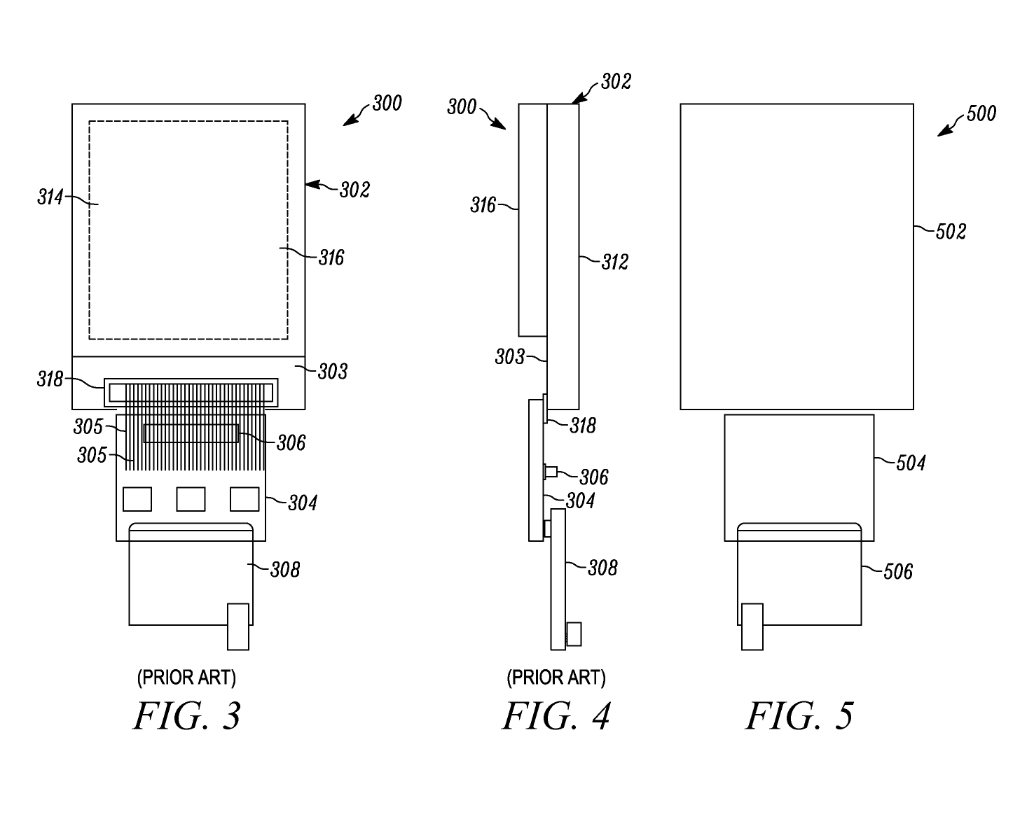

The display assembly 300 (FIGS. 3, 4, 5), according to another prior art structure, includes display 302, having a ledge 303 and a flex circuit 304. The ledge 303 can, for example, be an extension of display layer 312, which layer is referred to herein as the TFT substrate, and extends beyond front glass layer 316. The ledge 303 includes a flex connector 318 and traces for connection to the TFT circuit of the display. The flex circuit 304 carries traces 305 for the chip-on-flex (COF) structure for the driver IC 306. Flex circuit 304 is a bridging flex between display 302 and flex circuit 308. Ledge 303 carries a flex connector and traces for the COF structure illustrated in FIGS. 3-5. Display assembly 500 illustrates a plastic display assembly, including a display 502, with the flex circuit 504 connected to display 502 and display flex 506.

The ledge 108 carrying the driver IC 106 for the COG structure of FIG. 1, and the ledge 303 carrying traces for the driver IC 306 for the COF structure of FIG. 3, are dead space with respect to the display 102, 302. These ledges extend beyond the display active area 114, 314, and increase the dimensions of the display. The ledges enlarge the dimensions of a device that accommodates the larger display, but do not contain active pixels for image generation. The ledges 108, 303 thus extend their respective display dimensions without increasing the active display area, and prevent reduction of their respective borders in support of a designer's efforts to move toward a borderless display design.

Additionally, because the ledges 108, 303 extend a corresponding display border on an end or side, the use of such a ledge creates a non-uniform border. In smart phones, this ledge can add many millimeters to the border on one end, or side of the display, and may, for example, add 4 to 6 mm. The ledge typically introduces a 4.5 to 5.5 mm variation in the border on one end or side of the display. Thus, for square, circular, or rectangular active display regions, there will always be a side of the display assembly that is non-symmetrical due to the ledge, unless the border is uniformly enlarged around the entire display perimeter to match the ledge overhang of the TFT substrate. Such enlargement is undesirable as it enlarges the length and width of the device on all sides, and creates an even larger device and display dead space.

As described above, FIGS. 1 and 2 show a prior art driver IC 106 on ledge 108. Driver IC 106 may for example be mounted to TFT substrate 110, with the ledge 108 being an extension of the substrate 110. The illustrated flex circuit 104 connects to a flex connector (flex on glass I/O), which may for example be anisotropic conductive adhesive (ACF) bonded to TFT layer 110. The flex circuit includes electrical traces and provides a conduit for power management and transmission of data to the display. The flex circuit 104 provides connections for display power, driver IC, and touchscreen input. The driver IC 106 is mounted directly to glass to reduce cost and space requirements for accommodating the driver IC. The driver IC 106 may be on the flex, as shown in FIG. 3 or 5, but mounting the driver IC on the flex can be more complicated, and may utilize a jumper flex to carry the driver IC, the jumper flex connected to the flex circuit and the TFT circuit on the TFT substrate. The flex circuit 104 is shown including optional components, such as resistors, capacitors, or other components.

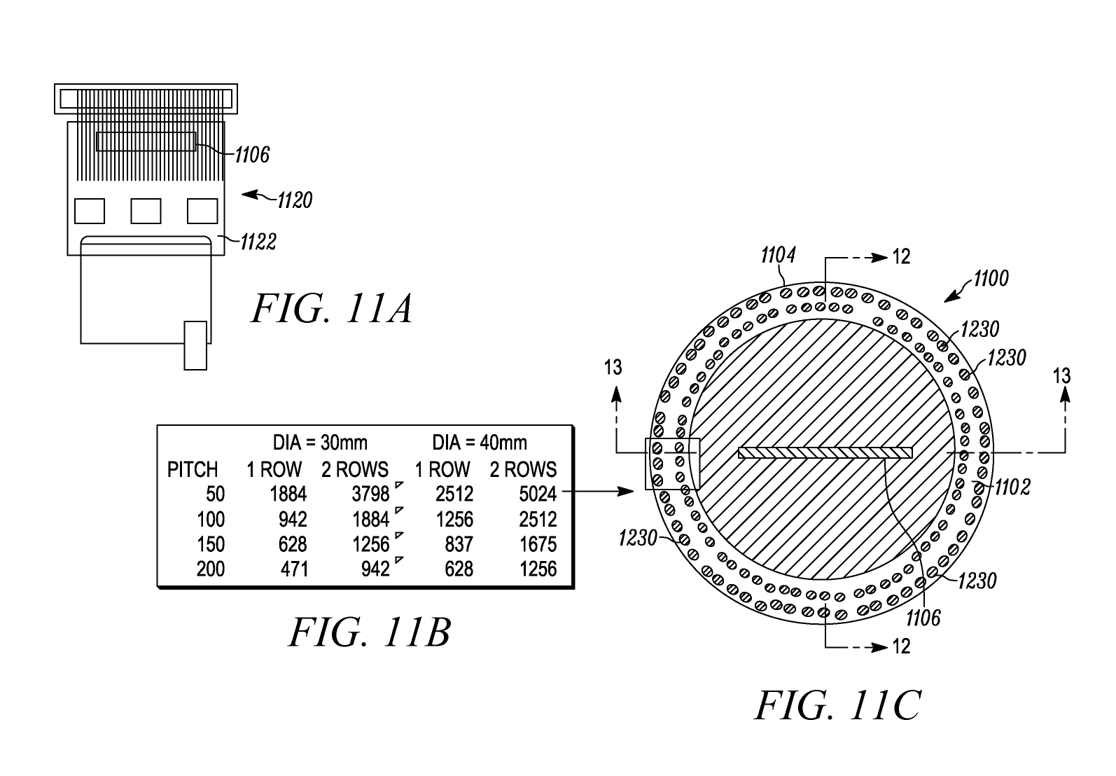

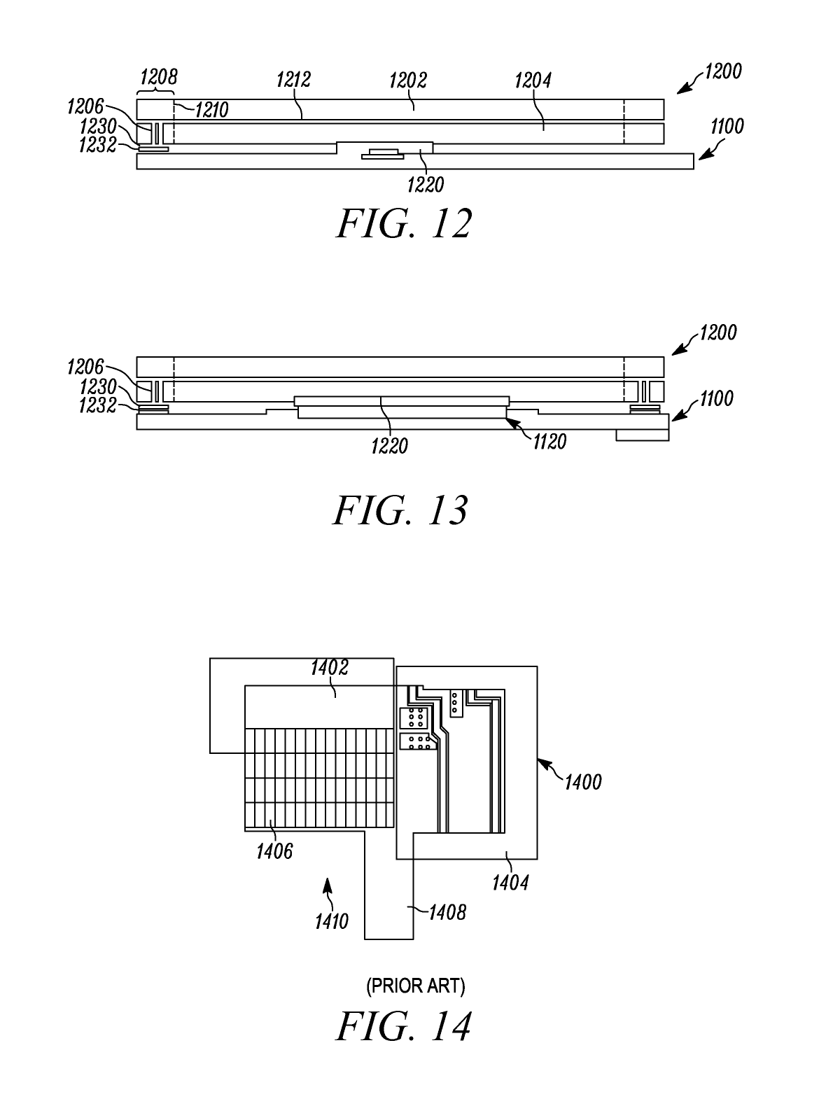

The display structure including a display flex assembly 1100 and a display assembly 1200 will now be described with reference to FIGS. 11A, 11B, 12, and 13. Referring to FIGS. 11A and 11B, a round display including a COF 1120 including a driver IC 1106 is illustrated, the COF 1106 attached to the display flex 1104, and the display flex 1104 attached to display 1200. The display flex 1104 may be attached to a printed circuit board (not shown). The COF 1120 may be bonded to display flex 1104 using eutectic bonding. The display flex assembly 1104 may be attached to a glass or plastic display TFT substrate 1212 of the display 1200 and the electrical connection made through vias 1206 in the TFT substrate of the display. A flex on flex ACF bond may be employed to attach the COF 1120 to the display flex 1100, the display flex having bonding pads 1230 in an I/O bonding zone 1102 on the perimeter of the display flex assembly and bonding zone 1208 on the perimeter of the display, the bonding pads making connection to via 1206 traces 1232 on the display when the display flex assembly is attached to the display assembly. The driver IC 1106 is mounted to the display flex 1104 and connected to the TFT substrate though the display flex circuit and the traces 1232. FIG. 11 is a plan view of a display flex assembly 1100 with a driver IC 1106 positioned on the display flex 1104. FIG. 12 is a cross-sectional view of the assembled display assembly including display flex assembly 1100, driver IC flex circuit 1120, and display assembly 1200, the cross-section being through the center of the display assembly orthogonal to the narrow width of the driver IC 1106. FIG. 13 is a cross-sectional view of the assembled display assembly including display flex assembly 1100, driver IC flex circuit 1120, and display assembly 1200, the cross-section being through the center of the display assembly orthogonal to the longitudinal axis of the driver IC 1106.

The improved display structure including a display flex assembly 1100 and a display assembly 1200 may be used with any suitable lens material, such as glass or plastic, and can employ vias through the bottom layer (TFT substrate) for routing conductors. The vias may be formed by any suitable process, and may for example be made using a laser, a drill, a punch, or the like. The vias may be made conductive using metal plating, such as copper, nickel, gold, silver, molybdemum, aluminum, or other conductive materials, including those commonly used for plating. Alternatively, the vias may be made conductive using conductive inks containing matrix materials, such as an adhesive with conductive filter such as carbon, silver, nickel, copper, gold, or other suitable material. Alternatively, the vias may be made conductive using conductive polymers such as PEDOT, PSS, PPV, or other materials, such as conductive conjugated polymers. Still another alternative is that the vias may be made conductive using nano materials, such nano silver, nano copper, mesh, carbon nanotubes, graphene, or other materials, or hybrids of metal, ink, conductive polymers. It is envisioned that the vias will be larger than the traces themselves, thus potentially requiring staggering in a very high density application, and necessitating slightly larger border space in such applications. On the back surface, the routing will be minimized and a large COF bonded to the back surface to connect the traces to the driver IC, or it is envisioned that the driver IC can be directly mounted on the back on the display as illustrated.

The improved display structure including a display flex assembly 1100 and a display assembly 1200 bonded around the perimeter at bonding zone 1102 on the perimeter of the display flex assembly and bonding zone 1208 on the perimeter of the display assembly provides a better perimeter seal as well as providing a very small uniform perimeter border Such a structure is beneficial for devices, such as wearable accessories. Furthermore NFC antennas, wireless charging, and printed circuit boards and components, can be readily integrated within the display assembly to facilitate construction of a laminate structure. On plastic displays, the vias may advantageously be encapsulated, and an ACF applied outside the region of the display in the area that includes the vias.

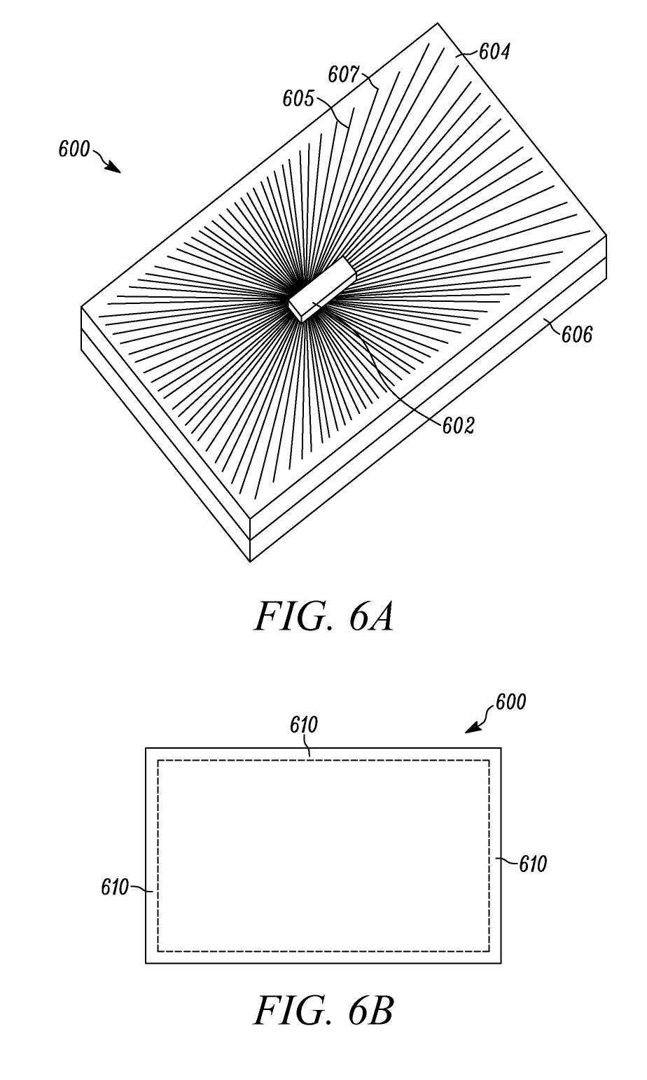

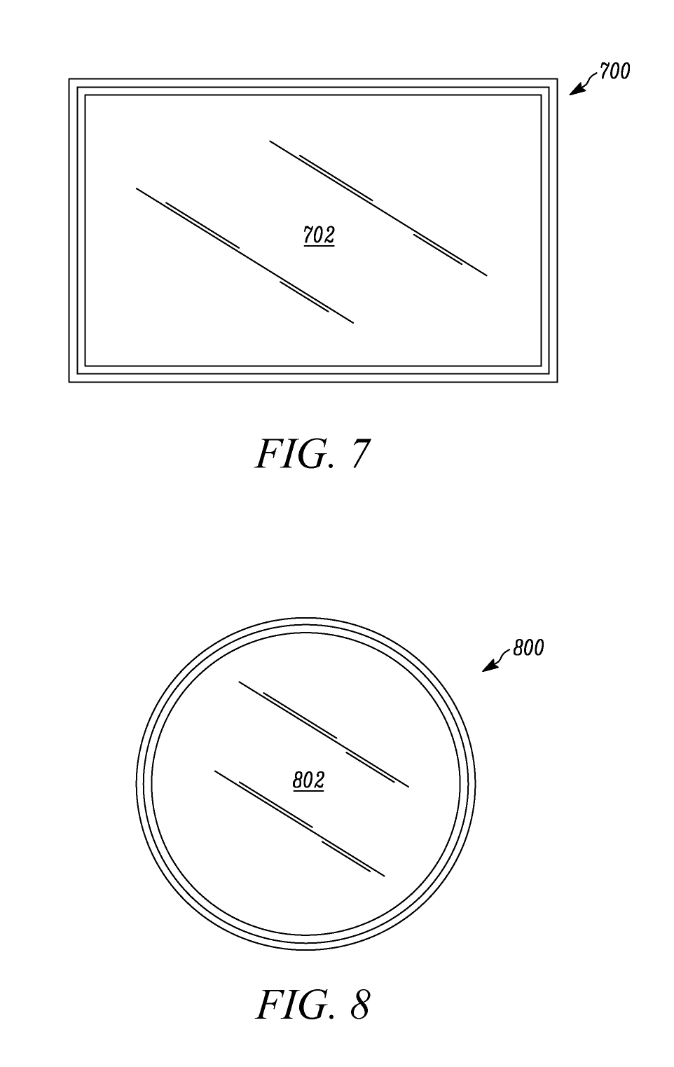

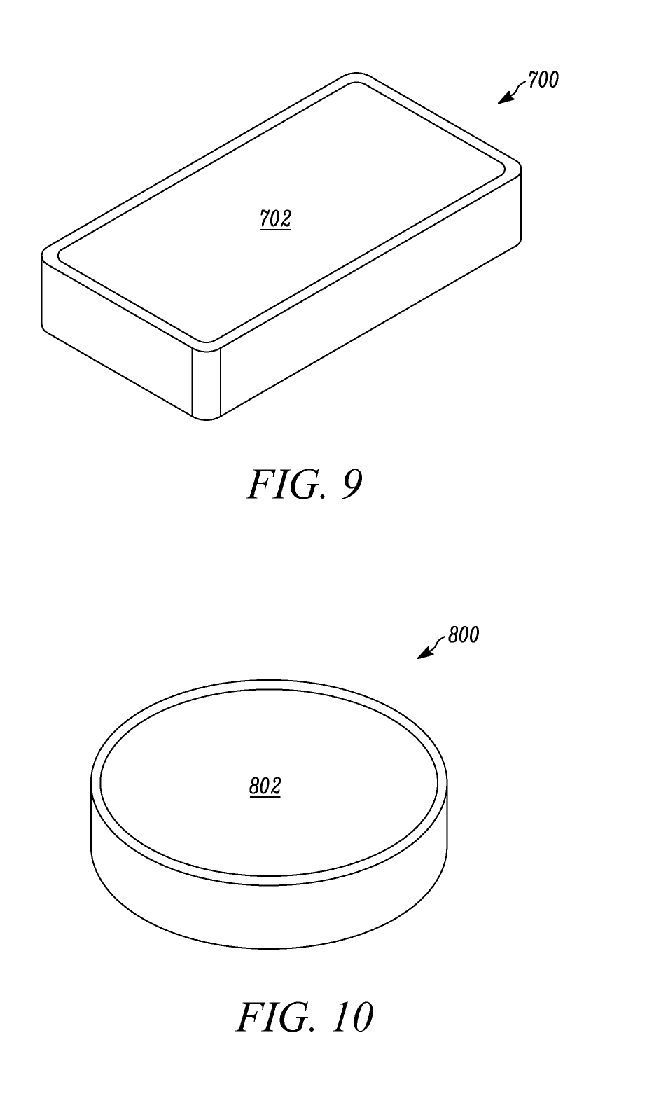

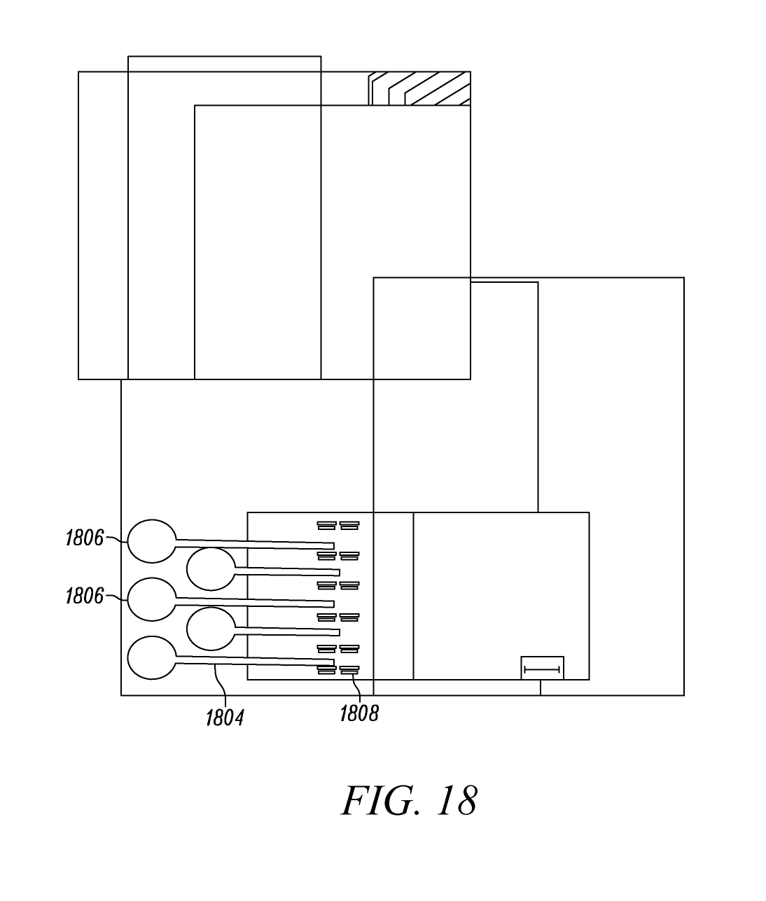

A display assembly 600 is illustrated in FIGS. 6A and 6B. Display assembly 600 may, for example, comprise an active matrix display, may have any pixel density, such as a high resolution or an ultra-high resolution display, and may advantageously have a pixel density of more than 200 pixels per square inch (PPI), and may be employed in a display with greater than 400 PPI. The active matrix display can be glass OLED, plastic OLED, electrophoretic, electrochromic, LCD, or other display technology. The display includes a driver IC 602 attached to the back surface of the TFT substrate 604 of the display. Traces 605 are routed through vias 607 through the TFT substrate layer, which are positioned just outside the active area of the display. Each of the traces extends through bottom layer 604, which may be plastic or glass, using the vias around the perimeter of the display or at the individual pixels themselves. It is envisioned that the vias can be located outside of the display active area, which is particularly advantageous with a plastic display, such as a polyimide display. The perimeter vias are positioned outside the display active area and they may be staggered (FIG. 18) for spacing and connection to active pixels, and the area adjacent to the vias may be used for bonding connection of the flex circuit to the back of the display as described above. That bonding can be achieved with ACF. Such construction allows the display to have a very small, uniform border 610 (FIG. 6B) circumscribing the entire active area of the display. Such a uniform small perimeter border enables unique device designs employing the display, such as for a rectangular smartphone 700 shown in FIGS. 7 and 9, with an edge-to-edge active area 702 over the entire front face, or a watch 800 shown in FIGS. 8 and 10 with a round edge-to-edge digital display active area 802.

It is envisioned that the display layers may be plastic or glass. The assembly can include:

### Example Glass Display

Driver IC is attached directly to back surface of TFT glass via ACF bonding, for chip on glass (COG).
Driver input/output (I/O) has Input I/Os and Output I/Os.
   Driver IC Output I/Os connect to active area of the display and control pixels (e.g., thin film transistor (TFT) pixels gates).
   Driver IC input I/Os connect to circuit on Flex via ACF bonded flex connector (flex I/O) and provides power and data.
ACF bonded for attaching driver IC for flex on glass (FOG).

### Example Plastic Display

Driver IC connected to flex, chip on flex (COF), using ACF eutectic bonding.
Flex connected to plastic display using ACF using FOP (Flex On Plastic)
   a. Example 1—Anisotropic Conductive Adhesive (ACF), which is conductive collapsible particles in adhesive film, is taped onto bond zone, bonding is achieved by a hot bar process.
   b. Example 2—Anisotropic Conductive Paste (ACP), which is conductive particles in adhesive paste, is dispensed onto bond zone. Bonding is achieved by a hot bar process.
   c. Example 3—Eutectic ACF, which is conductive particles are made of low melt temperature solder such as Sn—Bi, or the like. Bonding is achieved by a hot bar process.
   d. Example 4—Eutectic Bonding (EB), which is low temperature solder, is pasted onto bumps of IC or pads of Flex. Bonding is achieved by a hot bar process.

Regardless of which structure is used, COF or COG, or the shape of the display (which can be any shape such as round, square, rectangular, or non-symmetrical), to bond directly to the display rear surface of a glass or plastic display, the bonding is advantageously performed using low Temperature <<130 C+, low pressure hot bar process <<1 Mpa. Advantageously, the bonding and pressure may be applied on the perimeter of the display outside of the active viewing area, as described above, to eliminate the risk of damaging the display during the bonding process.

The example bonding provided herein for plastic can also be utilized with glass. With reference to FIG. 11A, the bond zone 1102 circumscribes an area aligned with the active area of the display 1100. The bond zone 1102 is an area of the display where adhesive can be applied, and heat and pressure can be supplied by a hot bar process to provide a bond. As shown in FIG. 12, this area 1208 of the display includes vias 1206 for electrical conductors that extend through the TFT glass substrate 1204. The COF 1120 including driver IC 1106 is ACF bonded to the display flex 1100. The display flex 1100 is bonded to the display 1200 perimeter I/O pads. An encapsulate material 1220 is provided for the driver IC 1106 and provides mechanical protection and fills the gap. The encapsulation material can be silicon, soft acrylic, or any other suitable material. The encapsulation material will most advantageously be a shock absorbing material to protect the display driver IC and flex by removing or reducing resulting loads off of the vias, the display, and minimizing the physical load on the driver.

In FIG. 12, the display flex is shown as being longer on one side. This extra length can be optional, and could be provided for a connector (not shown) or for connection to the device mother board (not shown). The extension may be omitted where the display flex is not intended to extend beyond the display.

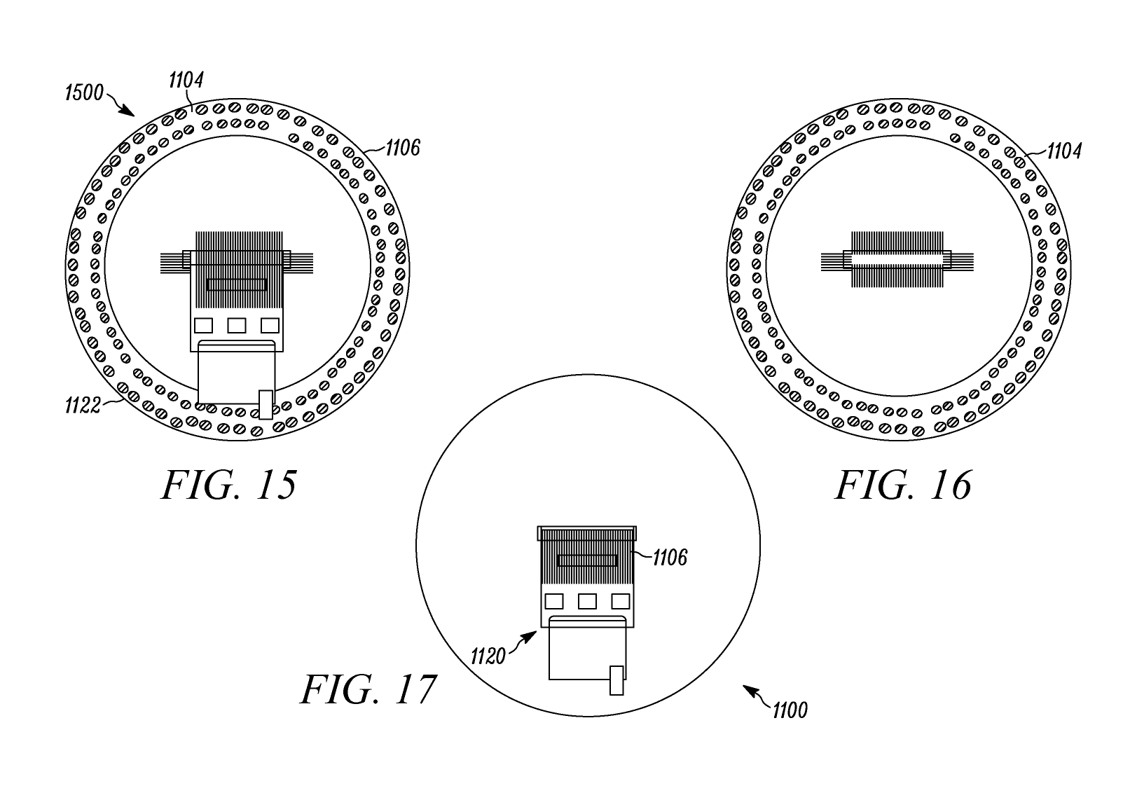

It is envisioned that the vias can circumscribe the perimeter with the exception of certain locations, such as the region of the perimeter where the COF 1120 extends from the display. For example, the vias can be omitted in the section of the perimeter where the flex extends over the display perimeter as shown in FIG. 15.

FIG. 11C is a table that illustrates possible via counts for a 30 or 40 mm round display, 1 row and 2 rows of vias, respectively. For even larger diameter displays, an even larger number of vias can be included in the perimeter bonding. The pitch can be extended to 400, and these pitches are offered as examples, and should not be considered limits. The perimeter can for example be 1.5 mm wide, but could be less than 1 mm. The above dimensions are provided by way of example.

FIG. 14 illustrates an enlarged corner including a row connect 1402, and column connect squares 1400, for the pixels 1406 in a rectangular display, such as those illustrated in FIGS. 1-5. The actual pixels are shown adjacent the column and row connections. A substantial surface area of the display is dedicated to routing connections 1400 and 1402, which connect the IC driver (not shown) to the pixels 1406 in the TFT substrate of the display. The improved display of FIG. 18 employs traces 1804 extending through vias 1806 as shown in FIG. 18, wherein the traces are connected directly to the pixels 1808. These direct connections 1804 may be used for both rows and columns to significantly reduce routing area on the surface of the display as compared to FIG. 14. By reducing the routing area, surface space on the glass or plastic layer is made available for bonding rather than routing, and the perimeter can be narrowed, increasing the active area. The illustrated example may include 100 um gates and 100 um vias.

The round display similarly includes offset vias around the perimeter to accommodate a sufficient number of traces for all of the pixels of the display. One, two, or more rows of vias may be provided around the perimeter depending on the size of the vias, the number of pixels, and perimeter dimension.

Although not specifically illustrated, it is envisioned that the device can include a touch layer.

FIG. 15 illustrates a COF display and a display including perimeter I/O pads. FIG. 16 illustrates a display flex bond zone with routing to the perimeter I/O pads. FIG. 17 illustrates a COF flex bonded to a display flex.

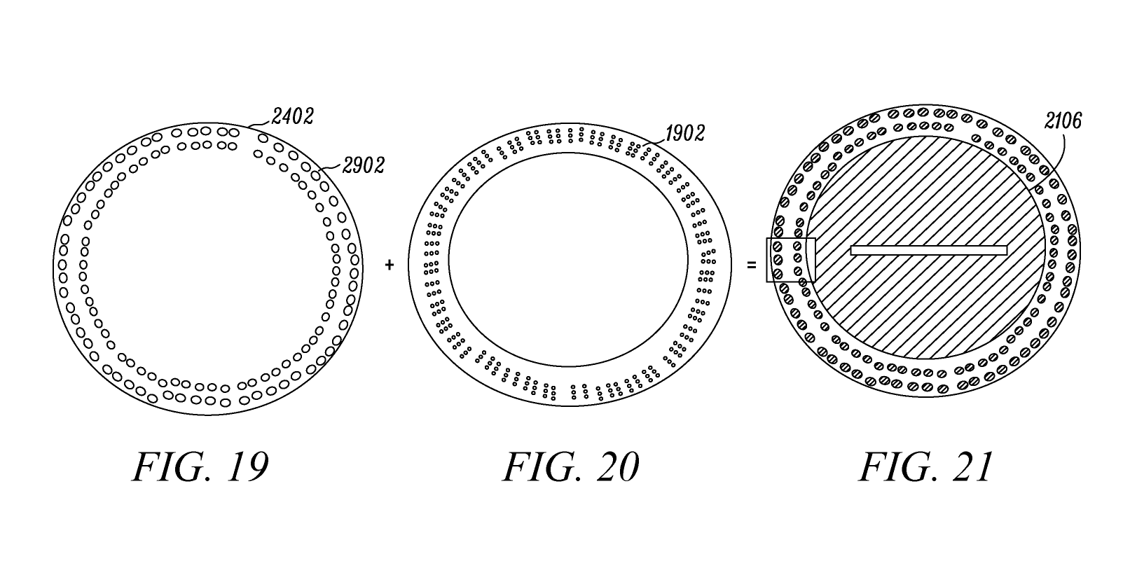

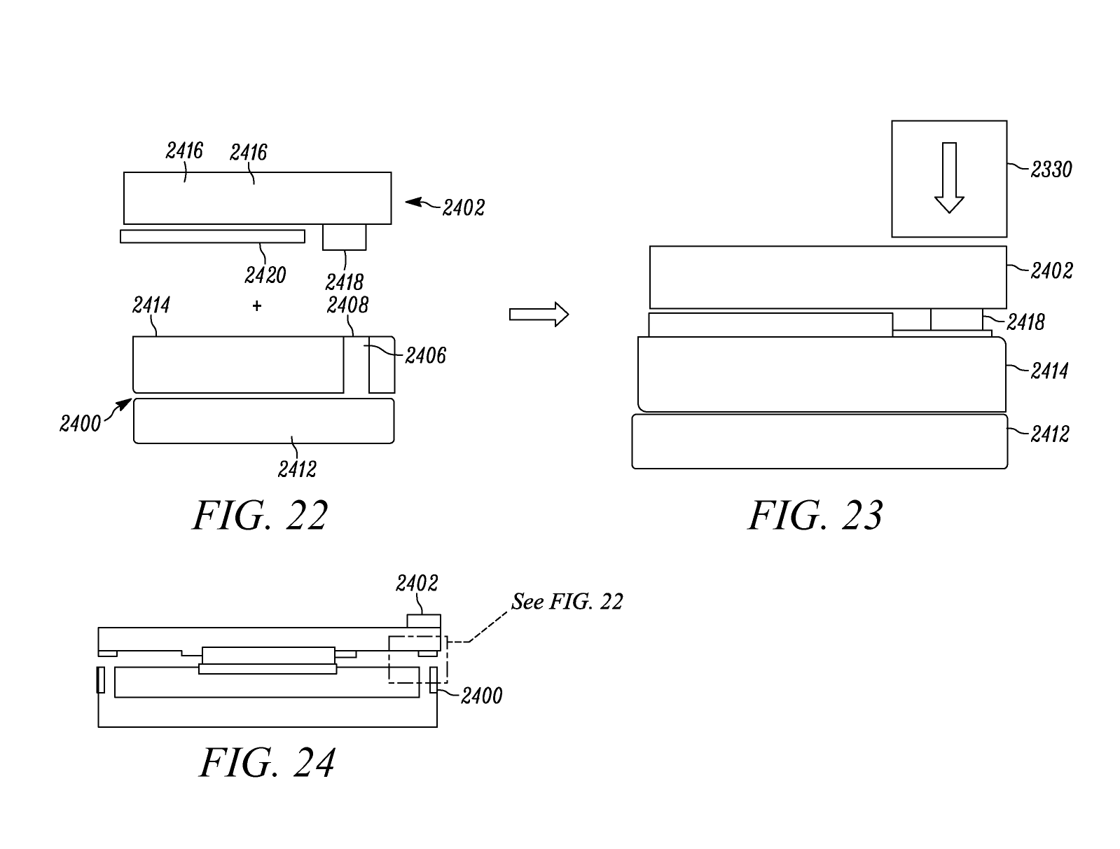

FIGS. 19, 20, 21, 22, 23, and 24 illustrate an example method of assembly. The display flex 1402 includes bonding pads 1902. The assembled display flex 2106 is illustrated in FIG. 21. The display structure can include a display flex assembly 2402 (FIG. 24) and a display assembly 2400. The electrical connection between the traces 2420 on the display flex and the rear surface TFT by the connection of the eutectic ACF paste 2418 attached to 2408 via land metalized ITO Ag paste fill metalized ITO via land I/O paste in via 2406. A hot bar may be employed for the reflow eutectic ACF, the hot bar applied at a temperature of 0 to 120 degrees Celsius and a pressure of 0.1 to 0.5 Mpa, for a suitable time such as 10 seconds, to bond the assembly. FIG. 24 illustrates the fully assembled display structure including the display assembly 2400, having rear surface TFT 2414 and Ecap 2412, and display flex assembly 2402. The display includes the TFT substrate having vias 2406 through the TFT substrate 2402. The display flex includes I/O pads around the perimeter. A respective via is provided in the TFT substrate for each bonding pad on the display flex, the vias and bonding pads aligned around the perimeter of the display structure.

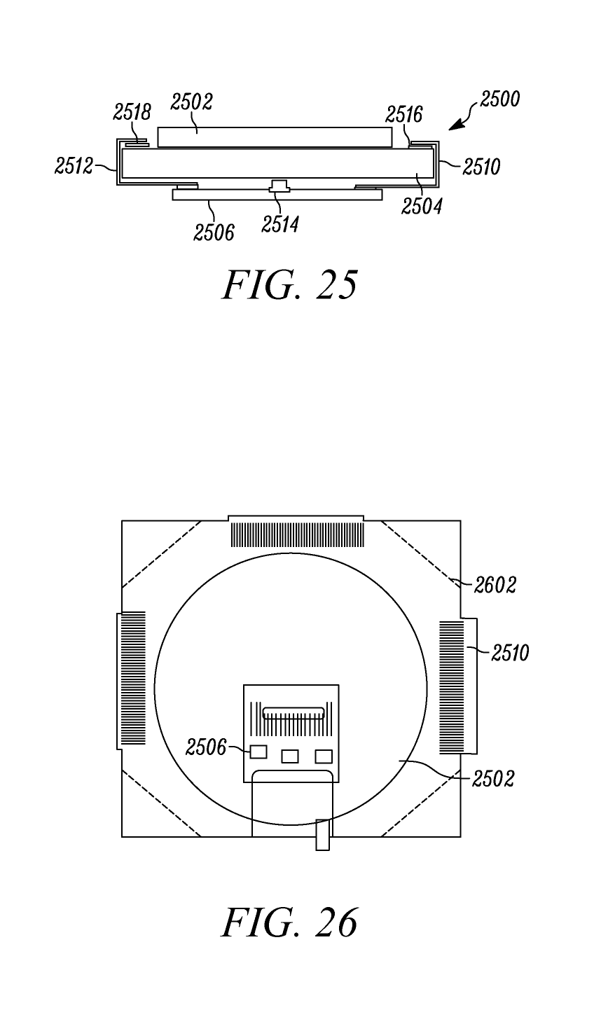

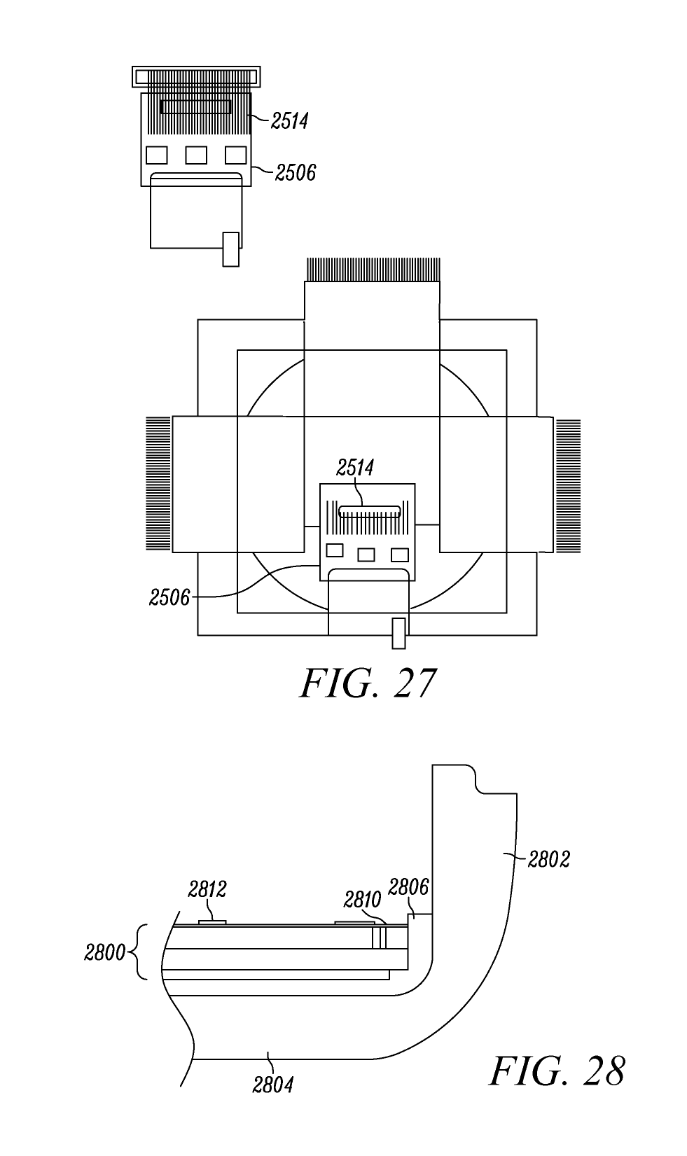

FIGS. 25, 26, and 27 illustrate another alternate display assembly 2500. The display 2500 includes a display front layer 2502 and bottom TFT layer 2504. Flex 2510 and flex 2512 are attached the TFT layer at bonds 2516 and 2518 and COF 2506 carrying Driver IC 2514.

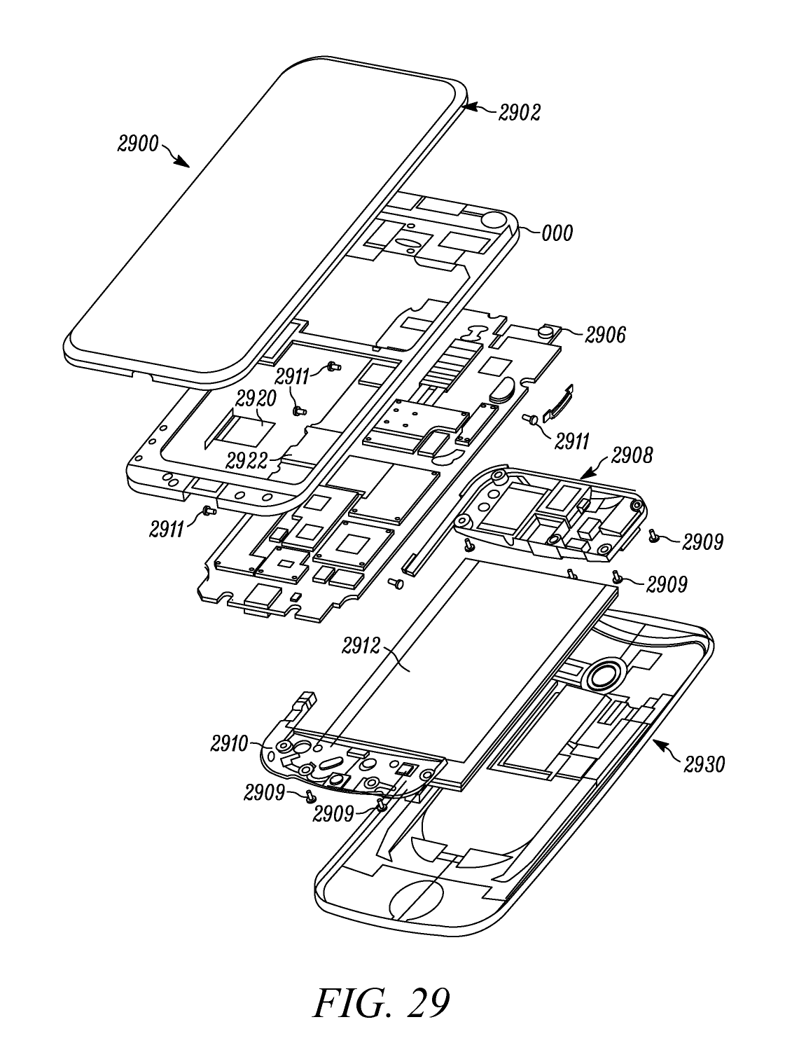

With reference to FIGS. 28 and 29, one example of an electronic display device 2900 is illustrated with the housing components exploded. The lens housing 2902 includes a laminated display assembly. An internal chassis 2904 is positioned behind the lens housing 2902. The chassis 2904 may be manufactured from any suitable material and can provide support for the housing. For instance, the housing 2904 may be metal, plastic or a suitable composite material, and may, for example, be stamped or die cast of any suitable metal, such as aluminum or a steel, or formed from a composite non-metal material, or molded plastic. The chassis 2904 may be a metal chassis having plastic over-molded sections in some areas of the chassis adjacent to which antennas will be positioned when the housing is fully assembled.

A printed circuit board (PCB) assembly 2906 is positioned adjacent the chassis 2904 when the device 2900 is assembled. The PCB assembly 2906 includes a circuit board on which electronic components are assembled. The electronic components include circuitry necessary to the operation of the display device 2900, which may also include circuitry for handling input of a touch screen component of the display (touch screen sensor). The PCB may be positioned completely within the chassis perimeter. The PCB may alternately be stacked onto the chassis 2904 with electrical components attached to the PCB positioned inside the chassis. A top antenna housing 2908 is attached to the chassis. The antenna housing 2908 may be manufactured by any suitable means, and may for example be molded with platable resin to create a desired antenna geometry. A bottom antenna housing 2910 is also attached to the chassis in the example device. The bottom antenna housing may also be advantageously molded with platable resin to create a desired antenna geometry. The top and bottom antenna housings 2908, 2910, clamp the PCB assembly 2906 to the chassis 2904 using suitable fasteners, such as screws 2909, clips (not shown), or the like. In the illustrated example, screws 2909 may be screwed into chassis 2904 or the printed circuit board assembly 2906.

The device 2900 is also illustrated to include a card tray 2920 for holding one or more of a memory and/or SIM card. The card tray 2920 may for example be an insert molded plastic and metal tray for holding the SIM card. The card tray 2920 slides into card bay 2922. The card bay is assembled onto the PCB assembly 2906.

The device 2900 may also include a battery 2912 behind the PCB assembly 2906.

Pins 2911 may be advantageously employed for assembling the electronic device, as will be described in greater detail herein below. The pins 2911 may be manufactured from any suitable material, such as stainless steel, aluminum, another metal, plastic, or a composite material. The pins 2911 are for insertion into the internal chassis 2904.

The rear housing 2930 may be manufactured from a composite material, such as an insert molded plastic, integrally bonded to a composite material, during a molding process. The composite material may be a sheet formed to the intended three dimensional shape of the rear housing, to provide a curved surface that is pleasant to hold, fitting comfortably in a hand when held. This shape may have a curvature in both the left-to-right side direction as well as a top-to-bottom end direction, where the curvature comprises the entire right-to-left direction and/or the entire top-to-bottom direction. Alternately, it may have a flat portion in one or both directions, where curved portions extend only near the edge regions.

With reference to FIG. 28, the front housing 2802 in the illustrated example may include a front housing laminate construction. The display 2800 is attached to the front housing wall 2802 and lens 2804 using a suitable adhesive 2806. The vias 2810 for the routing traces 2812 are located around the perimeter the display 2800.

By eliminating the lateral mounted components and/or flex, the length and/or width of the product can be reduced. Additionally, a uniform perimeter around the display with minimal border for the display enables an even edge-to-edge display circumscribing the entire display. Compact devices, such as wearable devices, and more particularly watches with LCD displays, incorporating the display are particularly advantageous as the display may be perfectly centered with a uniform perimeter. Additionally, the display enables greater integration of parts into the display which can ultimately make the product smaller.

For an LCD display, it is envisioned that the LCD can be a reflective liquid crystal display (LCD), with or without a front light.

As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, front and back, and the like, may be used solely to distinguish one entity from another without necessarily requiring or implying any actual such actual relationship or order between such entities.

While several embodiments of the disclosure have been illustrated and described, it is clear that the innovative concept is not so limited. Numerous modifications, changes, variations, substitutions, and equivalents will occur to those skilled in the art without departing from the scope of the present invention as defined by the following claims. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims.

What is claimed is:

1. A display assembly comprising:
a front layer, the front layer have a first surface facing out and a second surface parallel to the first surface;
a bottom layer, the bottom layer having a first surface for positioning toward the second surface of the front layer and a second surface parallel to the first surface of the bottom layer, the bottom layer further including vias along the perimeter edge in a bonding region; and
a driver IC, the driver IC carried on a bottom surface of the second surface of the bottom layer, the driver IC connected to traces carried on the second surface and extending through the vias, the traces connected to pixels used to generate images on the display.

2. The display assembly according to claim 1, wherein the bonding region circumscribes the perimeter of the display and has a substantially uniform width.

3. The display assembly according to claim 2, wherein the substantially uniform width is less than 1.6 mm around the entire perimeter of the active area of the display.

4. The display assembly according to claim 2, wherein the display is round.

5. A display assembly comprising:
a front layer, the front layer have a first surface facing out and a second surface parallel to the first surface;
a bottom layer, the bottom layer having a first surface for positioning toward the second surface of the front layer and a second surface parallel to the first surface of the bottom layer, the bottom layer further including vias along the perimeter edge in a bonding region;
a flex circuit; and
a driver IC, the driver IC carried on a flex circuit, the flex circuit connected to the second surface of the bottom layer, the driver IC connected to traces carried on the second layer, the traces running through the vias and connected to pixels used to generate images on the display.

6. An electronic device comprising:
a housing;
electrical components carried within the housing, the electrical components including processor;
a flex circuit connected to the electrical components;
a driver IC communicatively connected to the processor; and
a display having at least a first layer and a second layer, the display including pixels between the first and second layers, perimeter vias through the second layer, and traces through the vias and electrically coupled between the driver IC and the pixels.

7. The electronic device according to claim 6, wherein the driver IC is carried on the flex circuit, the flex circuit is bonded to the second layer of the display, and the flex traces are connected to the driver IC through the flex circuit.

8. The electronic device according to claim 6, wherein the driver IC is mounted to a surface of the second layer of the display, the flex traces are on the surface of the second layer and connected to the driver IC.
